(19) United States
(12) Patent Application Publication
(10) Pub. No.: US 2024/0301111 A1
(43) Pub. Date: Sep. 12, 2024

(54) RADIATION CURABLE RESIN

(71) Applicant: EVONIK OPERATIONS GMBH, Essen (DE)

(72) Inventors: Dinesh Kumar BASKER, Singapore (SG); Soumya SARKAR, Singapore (SG); Yili WU, Singapore (SG); Erwin PENG, Singapore (SG)

(73) Assignee: EVONIK OPERATIONS GMBH, Essen (DE)

(21) Appl. No.: 18/039,246

(22) PCT Filed: Nov. 19, 2021
(86) PCT No.: PCT/EP2021/082241

§ 371 Date: May 28, 2023

(30) Foreign Application Priority Data
Nov. 30, 2020 (EP) 20210550.8
Feb. 17, 2021 (EP) 21157664.0

(51) Int. Cl. C08F 265/06; B33Y 70/00; C08F 2/50

(52) U.S. Cl. CPC C08F 265/06; C08F 2/50; B33Y 70/00

(57) ABSTRACT

A liquid, radiation curable composition with a viscosity of 1500 cps or lower, said composition comprising 5 to 50 weight percent of monomeric or oligomeric component a) with at least two aromatic (meth)acrylate groups, 0 to 20 weight percent of monomeric or oligomeric component b) with at least two (meth)acrylate groups comprising an alicyclic moiety having at least three rings that are fused or condensed, 10 to 45 weight percent of aliphatic oligomeric or polymeric component c) with at least two (meth)acrylate groups comprising at least one urethane linkage, 10 to 30 weight percent of monomeric component d) with one (meth)acrylate group having at least one hydroxyl moiety, 0.5 to 6 weight percent of one or more photo-initiators capable of forming radicals and 0 to 5 weight percent of color pigments, with components a), b), c) and d) being different from each other.

The invention pertains to liquid, radiation curable composition suitable for additive manufacturing processes.

A well-established process of fabricating complex polymeric three-dimensional structure using stereolithography (SLA) and/or digital light processing (DLP) is called Vat-photopolymerization 3D printing or additive manufacturing (AM).

SLA/DLP processes utilizes CAD data of three-dimensional (3D) objects, which are converted to thin 2D slices. These 2D slices data are fed to a computer which controls a radiation sources such as laser or a light projector. Based on the 2D data, the radiation source would trace the pattern on a liquid radiation curable resin contained in the vat, leaving a solidified thin cross section of the corresponding 3D object. A thin layer of curable resin would be coated on the solidified cross section and the radiation source traces another cross section, obtained from the computer, on the resin layer to solidify over the previous solid layer. The process is repeated layer-by-layer to complete the fabrication of a 3D object. The 3D object is generally not fully cured and called green body, which could be subjected to post-curing processes to attain the final mechanical and thermal properties. Photopolymer for Vat-photopolymerization 3D printing or additive manufacturing (AM) technology is progressing from prototyping towards fabrication of functional end-use parts. One of the major challenges in using SLA/DLP based AM for manufacturing functional parts is the lack of high strength, high temperature resistant, durable liquid curable resin. Resin products available in the market are unable to provide the synergy of high strength, high temperature resistance and durability. Some of the high-strength resin materials currently available do not show acceptable durability or weatherability.

For example, U.S. Pat. No. 8,501,033 B2 describes a high strength liquid curable composition for three-dimensional printing. According to the composition disclosed in this document, high modulus of 2 to 3 GPa Young's modulus is attained. However, this composition contains a mixture of free radical and cationic curable moieties. It is known that such systems involving cationic curing moieties lead to limited shelf stability of the resin.

Attempts have been made to obtain high strength liquid curable resin using higher loading of methacrylate bisphenol type epoxides and other methacrylate monomers. Such resin compositions are described in U.S. Pat. No. 7,232,646B2 or US20180194885A1. The document US20180194885A1 shows such a composition which attains increased tensile strength of 35 to 40 MPa and a high Tg of 80° C. Such mechanical properties are not sufficient to meet the need of high-strength industrial applications. It is well-known in radiation curing polymer chemistry, that methacrylates are slow curing compared with acrylates. Consequently, the use of methacrylates results in lower green body strength during the additive manufacturing process. Furthermore, these compositions have a high number of aromatic moieties, which are susceptible to weathering induced degradation.

U.S. Ser. No. 10/357,435B2 discloses compositions with relatively lower loading of methacrylate bisphenol type epoxides to attain high strength resins. However, the viscosity of these compositions is significantly higher than resins with higher loading of methacrylate. Such compositions with higher viscosity are prone to generate processing limitations and may not be suitable for additive manufacturing of high-resolution objects.

It is thus an object of the present invention to provide a radiation curable composition in which the disadvantages of the prior art are at least reduced, which yields high strength objects after curing, that is suitable for additive manufacturing applications, and that achieves good weatherability.

This object is achieved by a liquid, radiation curable composition with a viscosity of 1500 cps or lower, said composition comprising the following components:
a) 5 to 50 weight percent of a monomeric or oligomeric component with at least two aromatic (meth)acrylate groups
b) 0 to 20 weight percent of monomeric or oligomeric component with at least two (meth)acrylate groups comprising an alicyclic moiety having at least three rings that are fused or condensed
c) 10 to 45 weight percent of aliphatic oligomeric or polymeric component with at least two (meth)acrylate groups comprising at least one urethane linkage
d) 10 to 30 weight percent of monomeric component with one (meth)acrylate group having at least one hydroxyl moiety
e) 0.5 to 6 weight percent of one or more photo-initiators capable of forming free radicals
f) 0 to 5 weight percent of color pigments
with components a), b), c) and d) being different from each other.

It is preferred that the sum of components a) to f) equals 100 weight percent.

The composition according to the invention can further comprise component g) additives to enhance processability and/or fillers in an amount of 0.01 to 30 weight percent. If component g) is present then the sum of components a) to g) equals 100 weight percent.

Surprisingly it was found that the resin composition according to the invention attains objects with high strength, high temperature resistance and at the same time excellent durability or weatherability using a single cure free radical system.

After curing, mechanical properties of the resin composition such as Young's modulus are in the range of at least 2.5 GPa and up to 5 GPa. Ultimate tensile strength and elongation at break are in the range of 70 to 120 MPa and 3.5%-7% respectively. Ultimate tensile strength, elongation at break and Young's modulus are determined according to ASTM D638.

The resin composition also leads to excellent thermal properties after curing. Heat distortion temperature lies in the range of 115° C. to 125° C. and glass transition temperature T_{g} is at least 90° C. and can reach up to 300° C. Heat distortion temperature was determined according to ASTM D648. Glass transition temperature T_{g} was determined at the onset of storage modulus in a dynamic mechanical analysis according to ASTM E1640.

The term “(meth)acrylate group” means either a methacrylate group, an acrylate group or a mixture of both.

The unique ratio of components a) to d) in the resin composition according to the invention results in a radiation curable liquid resin with a viscosity that is suitable for 3D printing applications and thus enabling superior processability. The viscosity of the liquid, radiation curable composition according to the invention preferably ranges from 100 to 1500 cps, 200-1500 cps, more preferably 300-1500 cps and most preferably 400-1500 cps. Viscosity is determined by applying the rotation rheometer method at 25° C. and 10 Hz.

The at least two aromatic (meth)acrylate groups in component a) of the liquid, radiation curable composition according to the invention are preferably aromatic di(meth)acrylates.

It is further preferred that component a) of the liquid, radiation curable composition according to the invention is selected from the group consisting of di(meth) acrylate of bisphenol A, Bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, bisphenol A propoxylate (2 PO/phenol) di(meth)acrylate, bisphenol A propoxylate (4 PO/phenol) di(meth)acrylate, bis(naphthol) di(meth)acrylate, bis(naphthol) ethoxylate (1 EO/naphthol) di(meth)acrylate, bis(anthrol) di(meth)acrylate, bis(anthrol) ethoxylate (1 EO/naphthol) di(meth)acrylate, as well as Bisphenol F di(meth)acrylate, bisphenol F ethoxylate (1 EO/phenol) di(meth)acrylate, bisphenol F ethoxylate (2 EO/phenol) di(meth)acrylate, bisphenol F ethoxylate (4 EO/phenol) di(meth)acrylate, bisphenol F propoxylate (1 PO/phenol) di(meth)acrylate, bisphenol F propoxylate (2 PO/phenol) di(meth)acrylate, bisphenol F propoxylate (4 PO/phenol) di(meth)acrylate or mixtures thereof.

The above preferred embodiments of component a) are obtainable by an addition reaction of an aromatic glycidyl group-containing compound and a (meth)acrylic acid, such as aromatic glycidyl ether. Alternatively, those substances can be obtained by an esterification reaction of an aromatic alcohol and (meth)acrylic acid.

The liquid, radiation curable composition according to the invention is preferably characterized in that the at least two (meth)acrylate groups in component b) are acryloxy unsaturated functional groups and that the alicyclic moiety is tricyclodecane or a derivative of tricyclodecane.

It is further preferred that the alicyclic moiety is selected from the group consisting of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane, 4-hydroxymethyl-8-methoxycarbonyl-tricyclo[5.2.1.0^{2,6}] decane, 3-hydroxymethyl-8-methoxycarbonyl-tricyclo[5.2.1.0^{2,6}] decane, 3-hydroxymethyl-9-methoxycarbonyl-tricyclo[5.2.1.0^{2,6}]decane, 4-hydroxymethyl-8-butoxycarbonyl tricyclo[5.2.1.0^{2,6}]decane, 3-hydroxymethyl-8-butoxycarbonyl-tricyclo[5.2.1.0^{2,6}] decane, 3-hydroxymethyl-9-butoxycarbonyl-tricyclo[5.2.1.0^{2,6}]decane, 4-hydroxymethyl-8-pentoxycarbonyl-tricyclo[5.2.1.0^{2,6}]decane, 3-hydroxymethyl-8-pentoxycarbonyl-tricyclo[5.2.1.0^{2,6}]decane, 3-hydroxymethyl-9-pentoxycarbonyl tricyclo[5.2.1.0^{2,6}]decane, 4-hydroxymethyl-8-vinyloxycarbonyl-tricyclo[5.2.1.0^{2,6}]decane, 3-hydroxymethyl-8-vinyloxycarbonyl-tricyclo[5.2.1.0^{2,6}]decane, 3-hydroxymethyl-9-vinyloxycarbonyl-tricyclo[5.2.1.0^{2,6}]decane. Most preferably from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane.

Component b) is preferably obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane, 4-hydroxymethyl-8-methoxycarbonyl-tricyclo[5.2.1.0^{2,6}] decane, 3-hydroxymethyl-8-methoxycarbonyl-tricyclo[5.2.1.0^{2,6}] decane, 3-hydroxymethyl-9-methoxycarbonyl-tricyclo[5.2.1.0^{2,6}]decane, 4-hydroxymethyl-8-butoxycarbonyl tricyclo[5.2.1.0^{2,6}]decane, 3-hydroxymethyl-8-butoxycarbonyl-tricyclo[5.2.1.0^{2,6}] decane, 3-hydroxymethyl-9-butoxycarbonyl-tricyclo[5.2.1.0^{2,6}]decane, 4-hydroxymethyl-8-pentoxycarbonyl-tricyclo[5.2.1.0^{2,6}]decane, 3-hydroxymethyl-8-pentoxycarbonyl-tricyclo[5.2.1.0^{2,6}]decane, 3-hydroxymethyl-9-pentoxycarbonyl tricyclo[5.2.1.0^{2,6}]decane, 4-hydroxymethyl-8-vinyloxycarbonyl-tricyclo[5.2.1.0^{2,6}]decane, 3-hydroxymethyl-8-vinyloxycarbonyl-tricyclo[5.2.1.0^{2,6}]decane, 3-hydroxymethyl-9-vinyloxycarbonyl-tricyclo[5.2.1.0^{2,6}]decane with (meth)acrylic acid.

Most preferably component b) is obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane with (meth)acrylic acid.

Difunctional components are perceived to be brittle after curing and the prior art suggests the use of monofunctional components (see e.g. US20180194885A1) for high strength resins. Surprisingly it could by shown that the resin composition according to the invention yields high strength mechanical properties by incorporating difunctional components.

Component c) according to the invention comprises at least two (meth)acrylate groups and at least one urethane linkage. For example, compounds formed by reacting an aliphatic polyol, for example a diol, with an aliphatic multifunctional isocyanate, for example, a diisocyanate, and then end-capping with an aliphatic hydroxy-functional (meth)acrylate or by reacting with an aliphatic multifunctional isocyanate, for example, a diisocyanate, and then end-capping with an aliphatic hydroxy-functional (meth)acrylate. The aliphatic polyol may be aliphatic polyether polyol or aliphatic hydrocarbon polyol. The aliphatic polyether polyols or aliphatic hydrocarbon polyol may be ethylene glycol, propylene glycol, tripropylene glycol, 1,3- or 1,4-butanediol, neopentylglycol, 1,6-hexanediol, 1,9-nonanediol, 1,10-decanediol. The aliphatic hydrocarbon diol/polyol may be hydroxyl terminated, fully or partially hydrogenated 1,2-propylene, butadiene, pentene, hexene. The aliphatic multifunctional isocyanate may be trimethylene diisocyanate, tetramethylene diisocyanate, hexamethylene diisocyanate, pentamethylene diisocyanate, 1,2-propylene diisocyanate, 1,2-butylene diisocyanate, 2,3-butylene diisocyanate, 1,3-butylene diisocyanate, 2,4,4- or 2,2,4-trimethylhexamethylene diisocyanate. The hydroxy-functional (meth) acrylate may be 2-hydroxyethyl (meth)acrylate, 2-hydroxypropyl (meth) acrylate, 2-hydroxybutyl (meth)acrylate, 4-hydroxybutyl (meth) acrylate, pentanediol mono(meth) acrylate, 2-hydroxyalkyl (meth) acryloyl phosphate, 4-hydroxycyclohexyl (meth)acrylate, glycerol mono (meth)acrylate, glycerol di (meth)acrylate, cyclohexane dimethanol mono(meth)acrylate, neopentyl glycol mono(meth) acrylate, trimethylolpropane di(meth)acrylate, and pentaerythritol tri(meth)acrylate. More preferably the aliphatic monomer, oligomer or polymer of component c) is obtained from the reaction of 2,4,4- or 2,2,4-trimethylhexamethylene diisocyanate and 2-hydroxyethyl (meth)acrylate.

Component d) could be a monomer or oligomer with at least one, e.g. with one, two or three (meth)acrylate groups having a terminal hydroxyl moiety. Examples for component d) with two or three (meth)acrylate groups are glycerol di (meth)acrylate, trimethylolpropane di(meth)acrylate, and pentaerythritol tri(meth)acrylate. According to the invention it is preferred that component d) is a monomer with one (meth)acrylate group having a terminal hydroxyl moiety. It is further preferred that the one (meth)acrylate group in component d) is a monofunctional acryloxy unsaturated functional group. Preferably component d) is an aliphatic monomer.

More preferably component d) is selected from the group consisting of 2-hydroxyethyl (meth)acrylate, 2-hydroxypropyl (meth) acrylate, 2-hydroxybutyl (meth)acrylate, 4-hydroxybutyl (meth) acrylate, pentanediol mono(meth) acrylate, 2-hydroxyalkyl (meth) acryloyl phosphate, 4-hydroxycyclohexyl (meth)acrylate, glycerol mono (meth)acrylate, cyclohexane dimethanol mono(meth)acrylate, neopentyl glycol mono(meth) acrylate or combinations thereof. In general component d) can be obtained by an addition reaction of a glycidyl group-containing compound and a (meth)acrylic acid, such as alkyl glycidyl ether and glycidyl (meth) acrylate and compounds which are obtainable by an esterification reaction of aliphatic alcohol and (meth)acrylic acid.

Component e) is preferably a free radical type photoinitiator selected from the group consisting of phosphine oxide-type photoinitiators and aromatic ketone-type photoinitiators or mixtures thereof.

The phosphine oxide-type of photoiniators may be a benzoyl diaryl phosphine oxide photoiniator, such as (2,4,6-trimethylbenzoyl) diphenylphosphine oxide or other phosphine oxide-type photo initiator, such as bis(2,4,6-trimethylbenzoyl)phenyphosphine or bis (2,6-dimethoxybenzoyl)-2,4,4-trimethylpentylphosphine oxide, and mixtures of phosphine oxide-type free radical photoinitiators. Examples of aromatic ketone-type free radical photoinitiators that may be used in the present invention include: 2-benzyl-2-N,N-dimethylamino-1-(4-morpholinophenyl)-1-butanone, 1-hydroxycyclohexylphenyl ketone, 2-hydroxy-2-methyl-1-phenylpropan-1-one, dimethoxyphenyl acetophenone, 2-methyl-1-4-methyl morpholinopropanone-1,1-(4-isopropylphenyl)-2-hydroxy-2-methylpropan-1-one, 1-(4-dodecyl-phenyl)-2-hydroxy-2-methylpropan-1-one, 4-(2-hydroxyethoxy)phenyl-2(2-hydroxy-2-propyl)-ketone. Also, the photoinitiator may be a mixture of phosphine oxide-type free radical photoinitiators and aromatic ketone type free radical photoinitiators. More preferably component e) is selected from the group consisting of benzoyl diaryl phosphine oxide photoiniator, such as (2,4,6-trimethylbenzoyl) diphenylphosphine oxide or other phosphine oxide-type photo initiator, such as bis(2,4,6-trimethylbenzoyl)phenyphosphine or bis (2,6-dimethoxybenzoyl)-2,4,4-trimethylpentylphosphine oxide.

Component f) can be any pigment that is known to the person skilled in the art. Preferably component f) is an organic or inorganic black pigment, examples of organic black are carbon black or aniline black and examples of inorganic black are titanium black and iron oxide.

Preferred embodiments of the liquid, radiation curable composition according to the invention:

In one preferred embodiment of the liquid, radiation curable composition according to the invention, the composition has a viscosity in the range of 100 cps to 1500 cps and it comprises the following components:
a) 5 to 50 weight percent of a monomeric or oligomeric component with at least two aromatic (meth)acrylate groups
b) 0 to 20 weight percent of a monomeric or oligomeric component with at least two (meth)acrylate groups comprising tricyclodecane or derivatives of tricyclodecane as alicyclic moiety
c) 10 to 45 weight percent of aliphatic oligomeric or polymeric component with at least two (meth)acrylate groups comprising at least one urethane linkage, the at least two (meth)acrylate groups being acryloxy unsaturated functional groups
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
with components a), b), c) and d) being different from each other.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component with at least two aromatic (meth)acrylate groups
b) 0 to 20 weight percent of a monomeric or oligomeric component with at least two (meth)acrylate groups comprising tricyclodecane or derivatives of tricyclodecane as alicyclic moiety
c) 10 to 45 weight percent of aliphatic oligomeric or polymeric component with at least two (meth)acrylate groups comprising at least one urethane linkage, the at least two (meth)acrylate groups being acryloxy unsaturated functional groups
d) 10 to 30 weight percent of an aliphatic monomer with at least one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
g) 0.1 to 30 weight percent of additives to enhance processability and/or fillers
with components a), b), c) and d) being different from each other and the sum of components a) to g) equals 100 weight percent.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component with at least two aromatic (meth)acrylate groups
b) 0 to 20 weight percent of a monomeric or oligomeric component with at least two (meth)acrylate groups comprising tricyclodecane or derivatives of tricyclodecane as alicyclic moiety
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
with components a), b), c) and d) being different from each other.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component with at least two aromatic (meth)acrylate groups
b) 0 to 20 weight percent of a monomeric or oligomeric component with at least two (meth)acrylate groups comprising tricyclodecane or derivatives of tricyclodecane as alicyclic moiety
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
g) 0.1 to 30 weight percent of additives to enhance processability and/or fillers
with components a), b), c) and d) being different from each other and the sum of components a) to g) equals 100 weight percent.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth) acrylate of bisphenol A, Bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, bisphenol A propoxylate (2 PO/phenol) di(meth)acrylate, bisphenol A propoxylate (4 PO/phenol) di(meth)acrylate, bis(naphthol) di(meth)acrylate, bis(naphthol) ethoxylate (1 EO/naphthol) di(meth)acrylate, bis(anthrol) di(meth)acrylate, bis(anthrol) ethoxylate (1 EO/naphthol) di(meth)acrylate, as well as Bisphenol F di(meth)acrylate, bisphenol F ethoxylate (1 EO/phenol) di(meth)acrylate, bisphenol F ethoxylate (2 EO/phenol) di(meth)acrylate, bisphenol F ethoxylate (4 EO/phenol) di(meth)acrylate, bisphenol F propoxylate (1 PO/phenol) di(meth)acrylate, bisphenol F propoxylate (2 PO/phenol) di(meth)acrylate, bisphenol F propoxylate (4 PO/phenol) di(meth)acrylate or mixtures thereof
b) 0 to 20 weight percent of a monomeric or oligomeric component with at least two (meth)acrylate groups comprising tricyclodecane or derivatives of tricyclodecane as alicyclic moiety
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
with components a), b), c) and d) being different from each other.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth) acrylate of bisphenol A, Bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, bisphenol A propoxylate (2 PO/phenol) di(meth)acrylate, bisphenol A propoxylate (4 PO/phenol) di(meth)acrylate, bis(naphthol) di(meth)acrylate, bis(naphthol) ethoxylate (1 EO/naphthol) di(meth)acrylate, bis(anthrol) di(meth)acrylate, bis(anthrol) ethoxylate (1 EO/naphthol) di(meth)acrylate, as well as Bisphenol F di(meth)acrylate, bisphenol F ethoxylate (1 EO/phenol) di(meth)acrylate, bisphenol F ethoxylate (2 EO/phenol) di(meth)acrylate, bisphenol F ethoxylate (4 EO/phenol) di(meth)acrylate, bisphenol F propoxylate (1 PO/phenol) di(meth)acrylate, bisphenol F propoxylate (2 PO/phenol) di(meth)acrylate, bisphenol F propoxylate (4 PO/phenol) di(meth)acrylate or mixtures thereof
b) 0 to 20 weight percent of a monomeric or oligomeric component with at least two (meth)acrylate groups comprising tricyclodecane or derivatives of tricyclodecane as alicyclic moiety
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
g) 0.1 to 30 weight percent of additives to enhance processability and/or fillers
with components a), b), c) and d) being different from each other and the sum of components a) to g) equals 100 weight percent.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth) acrylate of bisphenol A, Bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, bisphenol A propoxylate (2 PO/phenol) di(meth)acrylate, bisphenol A propoxylate (4 PO/phenol) di(meth)acrylate, bis(naphthol) di(meth)acrylate, bis(naphthol) ethoxylate (1 EO/naphthol) di(meth)acrylate, bis(anthrol) di(meth)acrylate, bis(anthrol) ethoxylate (1 EO/naphthol) di(meth)acrylate, as well as Bisphenol F di(meth)acrylate, bisphenol F ethoxylate (1 EO/phenol) di(meth)acrylate, bisphenol F ethoxylate (2 EO/phenol) di(meth)acrylate, bisphenol F ethoxylate (4 EO/phenol) di(meth)acrylate, bisphenol F propoxylate (1 PO/phenol) di(meth)acrylate, bisphenol F propoxylate (2 PO/phenol) di(meth)acrylate, bisphenol F propoxylate (4 PO/phenol) di(meth)acrylate or mixtures thereof
b) 0 to 20 weight percent of a monomeric or oligomeric component with at least two (meth)acrylate groups obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane with (meth)acrylic acid.
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
with components a), b), c) and d) being different from each other.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth) acrylate of bisphenol A, Bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, bisphenol A propoxylate (2 PO/phenol) di(meth)acrylate, bisphenol A propoxylate (4 PO/phenol) di(meth)acrylate, bis(naphthol) di(meth)acrylate, bis(naphthol) ethoxylate (1 EO/naphthol) di(meth)acrylate, bis(anthrol) di(meth)acrylate, bis(anthrol) ethoxylate (1 EO/naphthol) di(meth)acrylate, as well as Bisphenol F di(meth)acrylate, bisphenol F ethoxylate (1 EO/phenol) di(meth)acrylate, bisphenol F ethoxylate (2 EO/phenol) di(meth)acrylate, bisphenol F ethoxylate (4 EO/phenol) di(meth)acrylate, bisphenol F propoxylate (1 PO/phenol) di(meth)acrylate, bisphenol F propoxylate (2 PO/phenol) di(meth)acrylate, bisphenol F propoxylate (4 PO/phenol) di(meth)acrylate or mixtures thereof
b) 0 to 20 weight percent of a monomeric or oligomeric component with at least two (meth)acrylate groups obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane with (meth)acrylic acid.
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
g) 0.1 to 30 weight percent of additives to enhance processability and/or fillers
with components a), b), c) and d) being different from each other and the sum of components a) to g) equals 100 weight percent.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth)acrylate of bisphenol A, bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, or mixtures thereof
b) 0 to 20 weight percent of a monomeric or oligomeric component with at least two (meth)acrylate groups obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane with (meth)acrylic acid.
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
with components a), b), c) and d) being different from each other and with the sum of components a) to 0 equals 100 weight percent.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth)acrylate of bisphenol A, bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, or mixtures thereof
b) 0 to 20 weight percent of a monomeric or oligomeric component with at least two (meth)acrylate groups obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane with (meth)acrylic acid.
c) 10 to 45 weight percent of aliphatic oligomeric or polymeric component with at least two (meth)acrylate groups, the component is obtained by reacting an aliphatic polyol, preferably an aliphatic diol with an aliphatic multifunctional isocyanate, preferably an aliphatic diisocyanate and end-capping the reaction product with an aliphatic hydroxy-functional (meth)acrylate or by reacting an aliphatic multifunctional isocyanate, for example, a diisocyanate with an aliphatic hydroxy-functional (meth)acrylate
d) 10 to 30 weight percent of an aliphatic monomer with one (meth)acrylate group having a terminal hydroxyl moiety, said (meth)acrylate group being a monofunctional acryloxy unsaturated functional group
e) 0.5 to 6 weight percent of one or more photo-initiators capable of forming free radicals (single cure system), the one or more photo-initiators being selected from the group consisting of phosphine oxide-type photoinitiators and aromatic ketone-type photoinitiators
f) 0 to 5 weight percent of color pigments
g) 0.1 to 30 weight percent of additives to enhance processability and/or fillers
with components a), b), c) and d) being different from each other and with the sum of components a) to g) equals 100 weight percent.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth)acrylate of bisphenol A, bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, or mixtures thereof
b) 0 to 20 weight percent of a monomeric or oligomeric component with at least two (meth)acrylate groups obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane with (meth)acrylic acid.
c) 10 to 45 weight percent of aliphatic oligomeric or polymeric component with at least two (meth)acrylate groups, the component is obtained is obtained from the reaction of 2,4,4- or 2,2,4-trimethylhexamethylene diisocyanate and 2-hydroxyethyl (meth)acrylate
d) 10 to 30 weight percent of an aliphatic monomer selected from the group consisting of 2-hydroxyethyl (meth)acrylate, 2-hydroxypropyl (meth) acrylate, 2-hydroxybutyl (meth)acrylate, 4-hydroxybutyl (meth) acrylate, pentanediol mono(meth) acrylate, 2-hydroxyalkyl (meth) acryloyl phosphate, 4-hydroxycyclohexyl (meth)acrylate, glycerol mono (meth)acrylate, cyclohexane dimethanol mono(meth)acrylate, neopentyl glycol mono(meth) acrylate combinations thereof
e) 0.5 to 6 weight percent of one or more photo-initiators capable of forming free radicals, the one or more photo-initiators being selected from the group consisting of phosphine oxide-type photoinitiators and aromatic ketone-type photoinitiators
f) 0 to 5 weight percent of color pigments
with components a), b), c) and d) being different from each other and with the sum of components a) to f) equals 100 weight percent.

In another preferred embodiment of the liquid, radiation curable composition according to the invention, the composition has a viscosity in the range of 100 cps to 1500 cps and it comprises the following components:
a) 5 to 50 weight percent of a monomeric or oligomeric component selected from the group consisting of di(meth)acrylate of bisphenol A, bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, or mixtures thereof
b) 0 to 20 weight percent of a monomeric or oligomeric component with at least two (meth)acrylate groups obtained from the addition and/or esterification reaction of 48-Bis(hydroxymethyl)tricyclo[5.2.1.026]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane with (meth)acrylic acid.
c) 10 to 45 weight percent of aliphatic oligomeric or polymeric component with at least two (meth)acrylate groups, the component is obtained is obtained from the reaction of 2,4,4- or 2,2,4-trimethylhexamethylene diisocyanate and 2-hydroxyethyl (meth)acrylate
d) 10 to 30 weight percent of an aliphatic monomer selected from the group consisting of 2-hydroxyethyl (meth)acrylate, 2-hydroxypropyl (meth) acrylate, 2-hydroxybutyl (meth)acrylate, 4-hydroxybutyl (meth) acrylate, pentanediol mono(meth) acrylate, 2-hydroxyalkyl (meth) acryloyl phosphate, 4-hydroxycyclohexyl (meth)acrylate, glycerol mono (meth)acrylate, cyclohexane dimethanol mono(meth)acrylate, neopentyl glycol mono(meth) acrylate or combinations thereof
e) 0.5 to 6 weight percent of one or more photo-initiators capable of forming free radicals, the one or more photo-initiators being selected from the group consisting of phosphine oxide-type photoinitiators and aromatic ketone-type photoinitiators
f) 0 to 5 weight percent of color pigments
g) 0.1 to 30 weight percent of additives to enhance processability and/or fillers
with components a), b), c) and d) being different from each other and the sum of components a) to g) equals 100 weight percent.

The liquid, radiation curable composition according to the invention is a one-part system that requires no mixing of components immediately before the printing process. It is preferably curable through free radical curing in a single curing mechanism. More preferably the liquid, radiation curable composition according to the invention is curable by techniques selected from the group consisting of actinic radiation curing, electron beam curing, heat curing or combinations thereof.

The inventive liquid, radiation curable resin composition has a specific ratio of aliphatic to aromatic components for achieving high performance and durability or weatherability. Preferably the weight ratio of aromatic monomers or oligomers in the composition to aliphatic monomers or oligomers ranges from 5:95 to 50:50. More preferably the weight ratio of aromatic monomers or oligomers to aliphatic monomers or oligomers ranges from 5:95 to 30:70 (weight % aromatic:aliphatic).

Surprisingly it was also found that the mechanical properties and cure speed can be balanced by a unique ratio of methacrylate to acrylate in the liquid, radiation curable composition according to the invention. Preferably the weight ratio of methacrylate monomers or methacrylate oligomers to acrylate monomers or acrylate oligomers ranges from 80:20 to 20:80. More preferably the weight ratio of methacrylate monomers or methacrylate oligomers to acrylate monomers or acrylate oligomers ranges from 80:20 to 50:50 (weight % methacrylate:acrylate).

The resin composition according to the invention is especially suitable to be used in an additive manufacturing process or jetting process or a combination of both.

Such additive manufacturing processes or jetting processes for making a three-dimensional object are known in the art and generally comprising the steps of
(1) providing a liquid radiation curable resin:
(2) providing a 3D printer;
(3) coating a layer of a liquid radiation curable resin onto a surface;
(4) exposing said layer imagewise to actinic radiation to form a first exposed imaged cross-section, wherein the radiation is of sufficient intensity and time to cause substantial curing of the layer in the exposed areas;
(5) coating an additional layer of the liquid radiation curable resin onto the previously exposed imaged cross section;
(6) exposing said additional layer imagewise to actinic radiation to form an additional imaged cross-section, wherein the radiation is of sufficient intensity and time to cause substantial curing of the second layer in the exposed areas and to cause adhesion to the previously exposed imaged cross-section; and
(7) repeating steps (5) and (6) a desired number of times to build up the three-dimensional object.
The liquid radiation curable resin according to the invention can be used in such a process.

Preferably the liquid, radiation curable composition is used in an additive manufacturing or jetting process comprising the repeated steps of depositing or layering and irradiating the composition to form a three-dimensional object, more preferably the composition is used in an additive manufacturing or jetting process comprising the repeated steps of depositing or layering, heating, degassing and irradiating, the composition to form a three-dimensional object.

The invention also encompasses a three-dimensional object generated by an additive manufacturing process using a liquid, radiation curable composition according to the invention. Such a three-dimensional object satisfies the criteria for a high strength resin and exhibits a Young's modulus of at least 2.5 GPa and up to 5 GPa, an ultimate tensile strength of at least 70 MPa and up to 120 MPa. The glass transition temperature T_{g} is at least 90° C. and can reach up to 300° C. Ultimate tensile strength, and Young's modulus are measured according to ASTM D638. Glass transition temperature T_{g} is determined at the onset of storage modulus in a dynamic mechanical analysis according to ASTM E1640.

The three-dimensional object generated by an additive manufacturing process using a liquid, radiation curable composition according to the invention does not only yield a high strength material it also exhibits excellent ageing and weatherability properties.

Mechanical properties such as ultimate tensile strength and elongation at break are maintained even after exposure to UV radiation, temperature and moisture for 200 hours and the change in ultimate tensile strength is less than 50% even after exposure to UV radiation, temperature and moisture for 800 hours.

Thus, the present invention encompasses a three-dimensional object generated by an additive manufacturing process using a liquid, radiation curable composition according to the invention said three-dimensional object retains at least 50% of its ultimate tensile strength after being subjected to aging according to ASTM G154 for 800 hours.

The combination of both, high strength and good weatherability has not been reported in the art. The mechanical, thermal and durability or weatherability properties of the fully cured three-dimensional object generated from the inventive single cure low viscosity, three-dimensional printable, radiation curable liquid resin formulations are significantly better than prior art products. The resin compositions according to the invention can be used for SLA/DLP based 3D printing/additive manufacturing of high strength, temperature stable automotive and industrials thermoset components.

### EXAMPLES

The subject matter of the present invention is illustrated in more detail in the following examples, without any intention that the subject matter of the present invention be restricted to these examples.

### Procedures for Resin and Test Sample Preparation:

The resin is prepared by mixing the chemical ingredients as mentioned in the tables in a mixing equipment. The thus prepared resin mixture is used to generate tensile specimen through DLP 3D printing process.

Ultimate tensile strength, elongation at break and Young's modulus were determined according to ASTM D638.

Glass transition temperature T_{g} was determined at the onset of storage modulus in a dynamic mechanical analysis according to ASTM E1640.

### 1. Example 1

TABLE 1
liquid, radiation curable composition 1 according to the invention

| | | Percentage |
|---|---|---|
| Function | Chemical | (wt %) |
| Monomeric component a) | Bisphenol A glycerolate | 40 |
| | dimethacrylate | |
| Monomeric component b) | Tricyclo[5.2.1.0^{2, 6}]decane | 20 |
| | dimethanol diacrylate | |
| Monomeric component c) | Diurethane dimethacrylate | 20 |
| Monomeric component d) | 2-Hydroxyethyl methacrylate | 19 |
| Component e) Radical | Phenylbis(2,4,6- | 0.97 |
| Photoinitiator | trimethylbenzoyl) phosphine | |
| | oxide | |
| Component f) Pigment | Carbon black | 0.03 |

The viscosity of composition 1 measured by rotation rheometer method at 25° C. (10 Hz) was 800 cps.

TABLE 1a
Properties of tensile specimen after printing of composition 1
in DLP 3D printing process The printed tensile specimen exhibits
an ultimate tensile strength above 70 MPa and elongation at break in
the required range of 3.5-7%. Modulus is greater than 2.5 GPa and reaches
3.29 GPa. Glass transition temperature T_{g} lies in the required
range of 90 to 145° C. after complete curing.

| Properties of printed composition 1 | Values |
|---|---|
| Ultimate tensile strength (MPa) | 80 |
| Elongation at Break (%) | 4.2 |
| Young's Modulus (MPa) | 3290 |
| Glass transition temperature T_{g} (° C.) | 100 |

TABLE 1b
Aging properties of tensile specimen after printing of composition
1 in DLP 3D printing process and aging according to ASTM G154

| Aging properties of | % change | % change |
|---|---|---|
| printed composition 1 | (t₄₀₀) | (t₈₀₀) |
| Change in Ultimate tensile | −7.05 | −32.60 |
| strength (MPa) | | |

% change (t₄₀₀) After 400 hours of aging = ((Values after 400 hrs. aging (t₄₀₀) − Values before aging (t₀))/Values before aging (t₀)) * 100
% change (t₈₀₀) After 800 hours of aging = ((Values after 800 hrs. aging (t₈₀₀) − Values before aging (t₀))/Values before aging (t₀)) * 100

### 2. Example 2

TABLE 2
liquid, radiation curable composition 2 according to the invention

| | | Percentage |
|---|---|---|
| Function | Chemical | (wt %) |
| Monomeric component a) | Bisphenol A glycerolate | 35 |
| | diacrylate | |
| Monomeric component b) | Tricyclo[5.2.1.0^{2, 6}]decane | 20 |
| | dimethanol diacrylate | |
| Monomeric component c) | Diurethane dimethacrylate | 25 |
| Monomeric component d) | 2-Hydroxyethyl methacrylate | 19 |
| Component e) Radical | Phenylbis(2,4,6- | 1 |
| Photoinitiator | trimethylbenzoyl) phosphine | |
| | oxide | |

The viscosity of composition 2 measured by rotation rheometer method at 25° C. (10 Hz) was 600 cps.

TABLE 2a
Properties of tensile specimen after printing
of composition 2 in DLP 3D printing process.

| Properties of printed composition 2 | Values |
|---|---|
| Ultimate tensile strength (MPa) | 78.3 |
| Elongation at Break (%) | 4 |
| Young's Modulus (MPa) | 2960 |

The ultimate tensile strength of the tensile specimen is above 70. Elongation at break lies in the required range of 3.5-7%. Modulus is greater than 2.5 GPa and reaches 2.96 GPa.

TABLE 2b
Aging properties of tensile specimen after printing of composition
2 in DLP 3D printing process and aging according to ASTM G154

| Aging properties of | % change | % change |
|---|---|---|
| printed composition 2 | (t₄₀₀) | (t₈₀₀) |
| Change in Ultimate tensile | −3.22 | −7.56 |
| strength (MPa) | | |

% change (t₄₀₀) After 400 hours of aging = ((Values after 400 hrs. aging (t₄₀₀) − Values before aging (t₀))/Values before aging (t₀)) * 100
% change (t₈₀₀) After 800 hours of aging = ((Values after 800 hrs. aging (t₈₀₀) − Values before aging (t₀))/Values before aging (t₀)) * 100

### 3. Example 3

TABLE 3
liquid, radiation curable composition 3 according to the invention

| | | Percentage |
|---|---|---|
| Function | Chemical | (wt %) |
| Monomeric component a) | Bisphenol A glycerolate | 30 |
| | diacrylate | |
| Monomeric component b) | Tricyclo[5.2.1.0^{2, 6}]decane | 20 |
| | dimethanol diacrylate | |
| Monomeric component c) | Diurethane dimethacrylate | 30 |
| Monomeric component d) | 2-Hydroxyethyl methacrylate | 19 |
| Component e) Radical | Phenylbis(2,4,6- | 1 |
| Photoinitiator | trimethylbenzoyl) phosphine | |
| | oxide | |

The viscosity of composition 3 measured by rotation rheometer method at 25° C. (10 Hz) was 671 cps.

TABLE 3a
Properties of tensile specimen after printing
of composition 3 in DLP 3D printing process.

| Properties of printed composition 3 | Values |
|---|---|
| Ultimate tensile strength (MPa) | 84.1 |
| Elongation at Break (%) | 4.8 |
| Young's Modulus (MPa) | 2990 |

The ultimate tensile strength of the tensile specimen is above 70 and reaches 84.1 MPa. Elongation at break lies in the targeted range of 3.5-7%. Modulus is greater than 2.5 GPa and reaches 2.99 GPa.

TABLE 3b
Aging properties of tensile specimen after printing of composition
3 in DLP 3D printing process and aging according to ASTM G154

| Aging properties of | % change | % change |
|---|---|---|
| printed composition 3 | (t₄₀₀) | (t₈₀₀) |
| Change in Ultimate tensile | −13.34 | −18.45 |
| strength (MPa) | | |

% change (t₄₀₀) After 400 hours of aging = ((Values after 400 hrs. aging (t₄₀₀) − Values before aging (t₀))/Values before aging (t₀)) * 100
% change (t₈₀₀) After 800 hours of aging = ((Values after 800 hrs. aging (t₈₀₀) − Values before aging (t₀))/Values before aging (t₀)) * 100

### 4. Example 4

TABLE 4
liquid, radiation curable composition 4 according to the invention

| | | Percentage |
|---|---|---|
| Function | Chemical | (wt %) |
| Monomeric component a) | Bisphenol A glycerolate | 30 |
| | diacrylate | |
| Monomeric component b) | Tricyclo[5.2.1.0^{2, 6}]decane | 15 |
| | dimethanol diacrylate | |
| Monomeric component c) | Diurethane dimethacrylate | 35 |
| Monomeric component d) | 2-Hydroxyethyl methacrylate | 19 |
| Component e) Radical | Phenylbis(2,4,6- | 1 |
| Photoinitiator | trimethylbenzoyl) phosphine | |
| | oxide | |

The viscosity of composition 4 measured by rotation rheometer method at 25° C. (10 Hz) was 792 cps.

TABLE 4a
Properties of tensile specimen after printing
of composition 4 in DLP 3D printing process.

| Properties of printed composition 4 | Values |
|---|---|
| Ultimate tensile strength (MPa) | 78 |
| Elongation at Break (%) | 4.82 |
| Young's Modulus (MPa) | 3090 |

The ultimate tensile strength of the tensile specimen is above 70 and reaches 78 MPa. Elongation at break lies in the required range of 3.5-7%. Modulus is greater than 2.5 GPa and reaches 3.09 GPa.

TABLE 4b
Aging properties of tensile specimen after printing of composition
4 in DLP 3D printing process and aging according to ASTM G154

| Aging properties of | % change | % change |
|---|---|---|
| printed composition 4 | (t₄₀₀) | (t₈₀₀) |
| Change in Ultimate tensile | −7.31 | −16.17 |
| strength (MPa) | | |

% change (t₄₀₀) After 400 hours of aging = ((Values after 400 hrs. aging (t₄₀₀) − Values before aging (t₀))/Values before aging (t₀)) * 100
% change (t₈₀₀) After 800 hours of aging = ((Values after 800 hrs. aging (t₈₀₀) − Values before aging (t₀))/Values before aging (t₀)) * 100

### 5. Example 5

TABLE 5
liquid, radiation curable composition 5 according to the invention

| | | Percentage |
|---|---|---|
| Function | Chemical | (wt %) |
| Monomeric component a) | Bisphenol A glycerolate | 30 |
| | diacrylate | |
| Monomeric component b) | Tricyclo[5.2.1.0^{2, 6}]decane | 20 |
| | dimethanol diacrylate | |
| Monomeric component c) | Diurethane dimethacrylate | 35 |
| Monomeric component d) | 2-Hydroxyethyl methacrylate | 14 |
| Component e) Radical | Phenylbis(2,4,6- | 1 |
| Photoinitiator | trimethylbenzoyl) phosphine | |
| | oxide | |

TABLE 5a
Properties of tensile specimen after printing
of composition 10 in DLP 3D printing process

| Properties of printed composition 5 | Values |
|---|---|
| Ultimate tensile strength (MPa) | 73.3 |
| Elongation at Break (%) | 4.8 |
| Young's Modulus (MPa) | 2790 |

The ultimate tensile strength of the tensile specimen is above 70 MPa. Elongation at break lies within the targeted range of 3.5-7%. Modulus is greater than 2.5 GPa and reaches 2.79 GPa.

TABLE 5b
Aging properties of tensile specimen after printing of composition
5 in DLP 3D printing process and aging according to ASTM G154

| Aging properties of | % change | % change |
|---|---|---|
| printed composition 5 | (t₄₀₀) | (t₈₀₀) |
| Change in Ultimate tensile | −12.88 | −37.91 |
| strength (MPa) | | |

% change (t₄₀₀) After 400 hours of aging = ((Values after 400 hrs. aging (t₄₀₀) − Values before aging (t₀))/Values before aging (t₀)) * 100
% change (t₈₀₀) After 800 hours of aging = ((Values after 800 hrs. aging (t₈₀₀) − Values before aging (t₀))/Values before aging (t₀)) * 100

### 6. Example 6

TABLE 6
liquid, radiation curable composition 6 according to the invention

| | | Percentage |
|---|---|---|
| Function | Chemical | (wt %) |
| Monomeric component a) | Bisphenol A glycerolate | 50 |
| | diacrylate | |
| Monomeric component b) | Tricyclo[5.2.1.0^{2, 6}]decane | 20 |
| | dimethanol diacrylate | |
| Monomeric component c) | Diurethane dimethacrylate | 15 |
| Monomeric component d) | 2-Hydroxyethyl methacrylate | 14 |
| Component e) Radical | Phenylbis(2,4,6- | 1 |
| Photoinitiator | trimethylbenzoyl) phosphine | |
| | oxide | |

TABLE 6a
Properties of tensile specimen after printing
of composition 6 in DLP 3D printing process.

| Properties of printed composition 6 | Values |
|---|---|
| Ultimate tensile strength (MPa) | 75.0 |
| Elongation at Break (%) | 3.8 |
| Young's Modulus (MPa) | 3470 |

The ultimate tensile strength of the tensile specimen is above 70 MPa and reaches 75 MPa. Elongation at break lies within the targeted range of 3.5-7%. Modulus is greater than 2.5 GPa and reaches 3.47 GPa.

### 7. Example 7 (Comparative Example)

TABLE 7
liquid, radiation curable composition 7- comparative example

| | | Percentage |
|---|---|---|
| Function | Chemical | (wt %) |
| Monomeric component a) | Bisphenol A glycerolate | 60 |
| | dimethacrylate | |
| Monomeric component b) | Tricyclo[5.2.1.0^{2, 6}]decane | 07 |
| | dimethanol diacrylate | |
| Monomeric component c) | Diurethane dimethacrylate | 12 |
| Monomeric component d) | 2-Hydroxyethyl methacrylate | 20 |
| Component e) Radical | Phenylbis(2,4,6- | 0.97 |
| Photoinitiator | trimethylbenzoyl) phosphine | |
| | oxide | |
| Component f) Pigment | Carbon black | 0.03 |

Composition 7 is a comparative example with component a) exceeding 50 weight % of the composition. This leads to a viscosity of 3570 cps determined by rotation rheometer method at 25° C. (10 Hz).

Properties of tensile specimen after printing of composition 7 in DLP 3D printing process could not be measured. The material was too brittle for testing and the viscosity of the composition is beyond the desirable range for printing. Going beyond the weight range of 50 weight percent of component a) according to the invention impacts the viscosity of the composition significantly.

1-15. (canceled)

16. A liquid, radiation curable composition with a viscosity of 1500 cps or lower, said composition comprising the following components:
a) 5 to 50 weight percent of monomeric or oligomeric components with at least two aromatic (meth)acrylate groups;
b) 0 to 20 weight percent of monomeric or oligomeric components with at least two (meth)acrylate groups comprising an alicyclic moiety having at least three rings that are fused or condensed;
c) 10 to 45 weight percent of aliphatic oligomeric or polymeric components with at least two (meth)acrylate groups comprising at least one urethane linkage;
d) 10 to 30 weight percent of monomeric components with one (meth)acrylate group having at least one hydroxyl moiety;
e) 0.5 to 6 weight percent of one or more photo-initiators capable of forming radicals; and
f) 0 to 5 weight percent of color pigments;
with components a), b), c) and d) being different from each other.

17. The liquid, radiation curable composition of claim 16, wherein component a) is selected from the group consisting of: di(meth) acrylate of bisphenol A, Bisphenol A glycerolate di(meth)acrylate, bisphenol A ethoxylate (1 EO/phenol) di(meth)acrylate, bisphenol A ethoxylate (2 EO/phenol) di(meth)acrylate, bisphenol A ethoxylate (4 EO/phenol) di(meth)acrylate, bisphenol A propoxylate (1 PO/phenol) di(meth)acrylate, bisphenol A propoxylate (2 PO/phenol) di(meth)acrylate, bisphenol A propoxylate (4 PO/phenol) di(meth)acrylate, bis(naphthol) di(meth)acrylate, bis(naphthol) ethoxylate (1 EO/naphthol) di(meth)acrylate, bis(anthrol) di(meth)acrylate, bis(anthrol) ethoxylate (1 EO/naphthol) di(meth)acrylate, as well as Bisphenol F di(meth)acrylate, bisphenol F ethoxylate (1 EO/phenol) di(meth)acrylate, bisphenol F ethoxylate (2 EO/phenol) di(meth)acrylate, bisphenol F ethoxylate (4 EO/phenol) di(meth)acrylate, bisphenol F propoxylate (1 PO/phenol) di(meth)acrylate, bisphenol F propoxylate (2 PO/phenol) di(meth)acrylate, bisphenol F propoxylate (4 PO/phenol) di(meth)acrylate and mixtures thereof.

18. The liquid, radiation curable composition of claim 16, wherein the at least two (meth)acrylate groups in component b) are acryloxy unsaturated functional groups and the alicyclic moiety is tricyclodecane or a derivative of tricyclodecane.

19. The liquid, radiation curable of claim 17, wherein the at least two (meth)acrylate groups in component b) are acryloxy unsaturated functional groups and the alicyclic moiety is tricyclodecane or a derivative of tricyclodecane.

20. The liquid, radiation curable composition according to claim 18, wherein component b) is obtained from the addition and/or esterification reaction of 4,8-Bis(hydroxymethyl)tricyclo[5.2.1.0^{2,6}]decane, 4-hydroxymethyl-8-carboxy-tricyclo[5.2.1.0^{2,6}]decane, 3-hydroxymethyl-8-carboxy-tricyclo[5.2.1.0^{2,6}] decane, 3-hydroxymethyl-9-carboxy-tricyclo[5.2.1.0^{2,6}] decane, 4-hydroxymethyl-8-methoxycarbonyl-tricyclo[5.2.1.0^{2,6}] decane, 3-hydroxymethyl-8-methoxycarbonyl-tricyclo[5.2.1.0^{2,6}] decane, 3-hydroxymethyl-9-methoxycarbonyl-tricyclo[5.2.1.0^{2,6}]decane, 4-hydroxymethyl-8-butoxycarbonyl tricyclo[5.2.1.0^{2,6}]decane, 3-hydroxymethyl-8-butoxycarbonyl-tricyclo[5.2.1.0^{2,6}] decane, 3-hydroxymethyl-9-butoxycarbonyl-tricyclo[5.2.1.0^{2,6}]decane, 4-hydroxymethyl-8-pentoxycarbonyl-tricyclo[5.2.1.0^{2,6}]decane, 3-hydroxymethyl-8-pentoxycarbonyl-tricyclo[5.2.1.0^{2,6}]decane, 3-hydroxymethyl-9-pentoxycarbonyl tricyclo[5.2.1.0^{2,6}]decane, 4-hydroxymethyl-8-vinyloxycarbonyl-tricyclo[5.2.1.0^{2,6}]decane, 3-hydroxymethyl-8-vinyloxycarbonyl-tricyclo[5.2.1.0^{2,6}]decane, or 3-hydroxymethyl-9-vinyloxycarbonyl-tricyclo[5.2.1.0^{2,6}]decane with (meth)acrylic acid.

21. The liquid, radiation curable composition of claim 16, wherein the at least two (meth)acrylate groups in component c) are acryloxy unsaturated functional groups and component c) is obtained by reacting an aliphatic polyol with an aliphatic multifunctional isocyanate and end-capping with an aliphatic hydroxy-functional (meth)acrylate or by reacting an aliphatic multifunctional isocyanate with an aliphatic hydroxy-functional (meth)acrylate.

22. The liquid, radiation curable composition of claim 16, wherein component d) is selected from the group consisting of: 2-hydroxyethyl (meth)acrylate, 2-hydroxypropyl (meth) acrylate, 2-hydroxybutyl (meth)acrylate, 4-hydroxybutyl (meth) acrylate, pentanediol mono(meth) acrylate, 2-hydroxyalkyl (meth) acryloyl phosphate, 4-hydroxycyclohexyl (meth)acrylate, glycerol mono (meth)acrylate, cyclohexane dimethanol mono(meth)acrylate, neopentyl glycol mono(meth) acrylate and combinations thereof.

23. The liquid, radiation curable composition of claim 22, wherein the composition is curable through free radical curing.

24. The liquid, radiation curable composition according to claim 23, characterized in that the composition is curable by techniques selected from the group consisting of actinic radiation curing, electron beam curing, heat curing or combinations thereof.

25. The liquid, radiation curable composition of claim 17, wherein the at least two (meth)acrylate groups in component c) are acryloxy unsaturated functional groups and component c) is obtained by reacting an aliphatic polyol with an aliphatic multifunctional isocyanate and end-capping with an aliphatic hydroxy-functional (meth)acrylate or by reacting an aliphatic multifunctional isocyanate with an aliphatic hydroxy-functional (meth)acrylate.

26. The liquid, radiation curable composition of claim 25, wherein component d) is selected from the group consisting of: 2-hydroxyethyl (meth)acrylate, 2-hydroxypropyl (meth) acrylate, 2-hydroxybutyl (meth)acrylate, 4-hydroxybutyl (meth) acrylate, pentanediol mono(meth) acrylate, 2-hydroxyalkyl (meth) acryloyl phosphate, 4-hydroxycyclohexyl (meth)acrylate, glycerol mono (meth)acrylate, cyclohexane dimethanol mono(meth)acrylate, neopentyl glycol mono(meth) acrylate and combinations thereof.

27. The liquid, radiation curable composition of claim 16, wherein the composition is curable through free radical curing.

28. The liquid, radiation curable composition according to claim 27, characterized in that the composition is curable by techniques selected from the group consisting of actinic radiation curing, electron beam curing, heat curing or combinations thereof.

29. The liquid, radiation curable composition of claim 16, wherein the weight ratio of aromatic monomers or oligomers in the composition to aliphatic monomers or oligomers ranges from 5:95 to 50:50.

30. The liquid, radiation curable composition of claim 16, wherein the weight ratio of methacrylate monomers or oligomers to acrylate monomers or oligomers ranges from 80:20 to 20:80.

31. The liquid, radiation curable composition of claim 30, wherein the viscosity of the composition ranges from 100 to 1500 cps at 25° C.

32. The liquid, radiation curable composition of claim 16, wherein the viscosity of the composition ranges from 100 to 1500 cps at 25° C.

33. An additive manufacturing or jetting process comprising the repeated steps of depositing or layering and irradiating the composition of claim 16 to form a three-dimensional object.

34. The additive manufacturing or jetting process of claim 33, wherein the three-dimensional object has a Young's modulus of at least 2.5 GPa, an ultimate tensile strength of at least 70 MPa and a glass transition temperature T_{g} at the onset of storage modulus of at least 90° C.

35. The three-dimensional object of claim 33, wherein the three dimensional object retains at least 50% of its ultimate tensile strength after being subjected to aging according to ASTM G154 for 800 hours.
